(19) United States
(12) Patent Application Publication
(10) Pub. No.: US 2007/0237895 A1
(43) Pub. Date: Oct. 11, 2007

(54) METHOD AND SYSTEM FOR INITIATING A DEPOSITION PROCESS UTILIZING A METAL CARBONYL PRECURSOR

(75) Inventors: Kenji Suzuki, Guilderland, NY (US); Atsushi Gomi, Rensselaer, NY (US)

Correspondence Address: WOOD, HERRON & EVANS, LLP (TOKYO ELECTRON), 2700 CAREW TOWER, 441 VINE STREET, CINCINNATI, OH, 45202, US

(73) Assignee: Tokyo Electron Limited, Tokyo (JP)

(21) Appl. No.: 11/278,060

(22) Filed: Mar. 30, 2006

(51) Int. Cl. C23C 16/00; G06F 19/00

(52) U.S. Cl. 427/255.28; 700/121

(57) ABSTRACT

A method and system for initiating a deposition process utilizing a metal carbonyl precursor and CO as a delivery gas is described. Prior to a deposition process in a deposition chamber, a flow of delivery gas comprising CO is established through a vaporization system to transport a precursor vapor to an exhaust system while bypassing the deposition chamber. During the flow of the CO gas and vapor precursor to the evacuation system, a purge gas, such as an inert gas, or CO, or a combination thereof, can be introduced to the deposition chamber. Once a stable flow of CO gas and precursor vapor is established, the CO gas and precursor vapor are introduced to the deposition chamber while the purge gas is terminated.

### BACKGROUND OF THE INVENTION

1. Field of Invention

The present invention relates to a method and system for thin film deposition, and more particularly to a method and system for initiating a process for depositing a thin film using a metal carbonyl precursor.

2. Description of Related Art

The introduction of copper (Cu) metal into multilayer metallization schemes for manufacturing integrated circuits can necessitate the use of diffusion barriers/liners to promote adhesion and growth of the Cu layers and to prevent diffusion of Cu into the dielectric materials. Barriers/liners that are deposited onto dielectric materials can include refractive materials, such as tungsten (W), molybdenum (Mo), and tantalum (Ta), that are non-reactive and immiscible in Cu, and can offer low electrical resistivity. Current integration schemes that integrate Cu metallization and dielectric materials can require barrier/liner deposition processes at substrate temperature between about 400° C. and about 500° C., or lower.

For example, Cu integration schemes for technology nodes less than or equal to 130 nm can utilize a low dielectric constant (low-k) inter-level dielectric, followed by a physical vapor deposition (PVD) Ta layer or a TaN/Ta layer, followed by a PVD Cu seed layer, and an electro-chemical deposition (ECD) Cu fill. Generally, Ta layers are chosen for their adhesion properties (i.e., their ability to adhere on low-k films), and Ta/TaN layers are generally chosen for their barrier properties (i.e., their ability to prevent Cu diffusion into the low-k film).

As described above, significant effort has been devoted to the study and implementation of thin transition metal layers as Cu diffusion barriers, these studies including such materials as chromium, tantalum, molybdenum and tungsten. Each of these materials exhibits low miscibility in Cu. More recently, other materials, such as ruthenium (Ru) and rhodium (Rh), have been identified as potential barrier layers since they are expected to behave similarly to conventional refractory metals. However, the use of Ru or Rh can permit the use of only one barrier layer, as opposed to two layers, such as Ta/TaN. This observation is due to the adhesive and barrier properties of these materials. For example, one Ru layer can replace the Ta/TaN barrier layer. Moreover, current research is finding that the one Ru layer can further replace the Cu seed layer, and bulk Cu fill can proceed directly following Ru deposition. This observation is due to good adhesion between the Cu and the Ru layers.

Conventionally, Ru layers can be formed by thermally decomposing a ruthenium-containing precursor, such as a ruthenium carbonyl precursor, in a thermal chemical vapor deposition (TCVD) process. Material properties of Ru layers that are deposited by thermal decomposition of ruthenium carbonyl precursors (e.g., Ru₃(CO)₁₂) can deteriorate when the substrate temperature is lowered to below about 400° C. As a result, an increase in the (electrical) resistivity of the Ru layers and poor surface morphology (e.g., the formation of nodules) at low deposition temperatures has been attributed to increased incorporation of reaction by-products into the thermally deposited Ru layers. Both effects can be explained by a reduced carbon monoxide (CO) desorption rate from the thermal decomposition of the ruthenium carbonyl precursor at substrate temperatures below about 400° C.

Additionally, the use of metal carbonyls, such as ruthenium carbonyl or rhenium carbonyl, can lead to poor deposition rates due to their low vapor pressure, and the transport issues associated therewith. Overall, the inventors have observed that current deposition systems suffer from such a low rate, making the deposition of such metal films impractical. Furthermore, the inventors have observed that current deposition systems suffer from poor film uniformity.

### SUMMARY OF THE INVENTION

A method and apparatus are provided for initiating a process in a thin film deposition system.

Further yet, a method and apparatus are provided for initiating a process for depositing metal films using metal carbonyl precursors.

According to one embodiment, a method of depositing a metal layer on a substrate is described, the method comprising: providing a substrate within a deposition system; heating the substrate in the deposition system to a deposition temperature; establishing a flow of process gas containing a metal carbonyl precursor vapor and a CO gas to an exhaust system without introducing the flow of process gas to the deposition system for a duration of time; after the duration of time, introducing the flow of process gas to the deposition system; and exposing the substrate to the process gas at the deposition temperature to deposit a metal layer on the substrate by a vapor deposition process. In another embodiment, the method may further include introducing a flow of purge gas to the deposition system, and then terminating the flow the purge gas prior to or concurrently with the introduction of the process gas to the deposition system.

### BRIEF DESCRIPTION OF THE DRAWINGS

In the accompanying drawings:

FIG. 1 depicts a schematic view of a deposition system according to an embodiment of the invention;

FIG. 2 depicts a schematic view of a deposition system according to another embodiment of the invention;

FIGS. 3A and 3B depict a process flow diagram for establishing a flow of vapor precursor to a deposition system according to one embodiment of the invention;

FIG. 4 illustrates a method of depositing a metal layer on a substrate according to an embodiment of the invention; and

FIGS. 5A through 5C schematically show, in cross-sectional views, formation of a metal layer on a patterned substrate according to embodiments of the invention.

### DETAILED DESCRIPTION OF PREFERRED EMBODIMENTS

In the following description, in order to facilitate a thorough understanding of the invention and for purposes of explanation and not limitation, specific details are set forth, such as a particular geometry of the deposition system and descriptions of various components. However, it should be understood that the invention may be practiced in other embodiments that depart from these specific details.

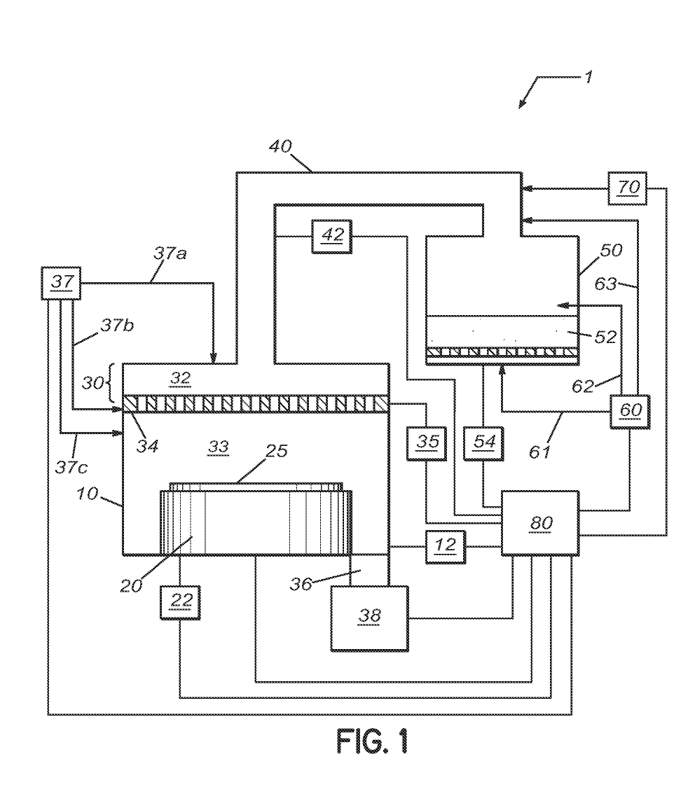

Referring now to the drawings, wherein like reference numerals designate identical or corresponding parts throughout the several views, FIG. 1 schematically illustrates a thermal chemical vapor deposition system 1 for depositing a metal layer on a substrate from a metal carbonyl precursor, according to one embodiment. While other metal carbonyl precursors may be used, embodiments of the invention may henceforth be described with particular reference to ruthenium carbonyl precursors, such as Ru₃(CO)₁₂, with the understanding that the invention is not so limited. The deposition system 1 comprises a process chamber 10 having a substrate holder 20 configured to support a substrate 25, upon which the metal layer is formed. The process chamber 10 is coupled to a metal precursor vaporization system 50 via a vapor precursor delivery system 40.

The process chamber 10 is further coupled to a vacuum pumping system 38 through a duct 36, wherein the pumping system 38 is configured to evacuate the process chamber 10, vapor precursor delivery system 40, and metal precursor vaporization system 50 to a pressure suitable for forming the metal layer on the substrate 25, and suitable for evaporation (or sublimation) of the metal carbonyl precursor 52 in the metal precursor vaporization system 50.

Still referring to FIG. 1, the metal precursor vaporization system 50 is configured to store a metal carbonyl precursor 52, to heat the metal carbonyl precursor 52 to a temperature sufficient for vaporizing the metal carbonyl precursor 52, and to introduce metal carbonyl precursor vapor to the vapor precursor delivery system 40. The metal carbonyl precursor 52 can be solid under the selected heating conditions in the metal precursor vaporization system 50. Alternately, the metal carbonyl precursor 52 can be a liquid. The terms “vaporization,” “sublimation” and “evaporation” are used interchangeably herein to refer to the general formation of a vapor (gas) from a solid or liquid precursor, regardless of whether the transformation is, for example, from solid to liquid to gas, solid to gas, or liquid to gas. Below, the use of a solid metal carbonyl precursor 52 is described; however, those skilled in the art will appreciate that metal carbonyl precursors that are liquids under the selected heating conditions can be used without departing from the scope of the invention. For instance, the metal carbonyl precursor can have the general formula Mₓ(CO)_{y}, and can comprise a tungsten carbonyl, a molybdenum carbonyl, a cobalt carbonyl, a rhodium carbonyl, a rhenium carbonyl, a chromium carbonyl, or an osmium carbonyl, or a combination of two or more thereof. These metal carbonyls include, but are not limited to, W(CO)₆, Ni(CO)₄, Mo(CO)₆, Co₂(CO)₈, Rh₄(CO)₁₂, Re₂(CO)₁₀, Cr(CO)₆, Ru₃(CO)₁₂, or Os₃(CO)₁₂, or a combination of two or more thereof.

In order to achieve the desired temperature for vaporizing the metal carbonyl precursor 52 (e.g., subliming the solid metal carbonyl precursor 52), the metal precursor vaporization system 50 is coupled to a vaporization temperature control system 54 configured to control the vaporization temperature. For instance, the temperature of the metal carbonyl precursor 52 is generally elevated to approximately 40° C. to 45° C. in conventional systems in order to sublime the ruthenium carbonyl Ru₃(CO)₁₂. At this temperature, the vapor pressure of the Ru₃(CO)₁₂, for instance, ranges from approximately 1 to approximately 3 mTorr. As the metal carbonyl precursor is heated to cause evaporation (or sublimation), a carrier gas can be passed over or through the metal carbonyl precursor 52, or any combination thereof. The carrier gas can include, for example, an inert gas, such as a noble gas, He, Ne, Ar, Kr, or Xe, or a combination of two or more thereof. Alternately, other embodiments contemplate omitting the inert carrier gas.

According to an embodiment of the invention, a CO gas can be added to the inert carrier gas. Alternately, other embodiments contemplate the CO gas replacing the inert carrier gas. For example, a gas supply system 60 is coupled to the metal precursor vaporization system 50, and it is configured to, for instance, supply a carrier gas, a CO gas, or a mixture thereof, beneath the metal carbonyl precursor 52 via feed line 61, or over the metal carbonyl precursor 52 via feed line 62. In addition, or in the alternative, the gas supply system 60 is coupled to the vapor precursor delivery system 40 downstream from the metal precursor vaporization system 50 to supply the gas to the vapor of the metal carbonyl precursor 52 via feed line 63 as or after it enters the vapor precursor delivery system 40. Although not shown, the gas supply system 60 can comprise a carrier gas source, a CO gas source, one or more control valves, one or more filters, and a mass flow controller. For instance, the flow rate of the inert carrier gas can be between about 0.1 standard cubic centimeters per minute (sccm) and about 1000 sccm. Alternately, the flow rate of the inert carrier gas can be between about 10 sccm and about 500 sccm. Still alternately, the flow rate of the inert carrier gas can be between about 50 sccm and about 200 sccm. According to embodiments of the invention, the flow rate of the CO gas can range from approximately 0.1 sccm to approximately 1000 sccm. Alternately, the flow rate of the CO gas can be between about 1 sccm and about 100 sccm.

Downstream from the film precursor vaporization system 50, the metal precursor vapor flows with the CO gas and optional inert carrier gas through the vapor delivery system 40 until it enters a vapor distribution system 30 coupled to or within the process chamber 10. The vapor delivery system 40 can be coupled to a vapor line temperature control system 42 in order to control the vapor line temperature and prevent decomposition of the film precursor vapor as well as condensation of the film precursor vapor. For example, the vapor line temperature can be set to a value approximately equal to or greater than the vaporization temperature. Additionally, for example, the vapor delivery system 40 can be characterized by a high conductance in excess of about 50 liters/second.

Referring again to FIG. 1, the vapor distribution system 30, coupled to the process chamber 10, comprises a plenum 32 within which the vapor disperses prior to passing through a vapor distribution plate 34 and entering a processing zone 33 above substrate 25. In addition, the vapor distribution plate 34 can be coupled to a distribution plate temperature control system 35 configured to control the temperature of the vapor distribution plate 34. For example, the temperature of the vapor distribution plate can be set to a value approximately equal to the vapor line temperature. However, it may be less, or it may be greater.

According to an embodiment of the invention, a dilution gas source 37 is coupled to the process chamber 10 and/or vapor distribution system 30 and is configured to add a dilution gas to dilute the process gas containing the metal carbonyl precursor vapor and the CO gas. As shown in FIG. 1, the dilution gas source 37 can be coupled to the vapor distribution system 30 via feed line 37a and configured to add the dilution gas to the process gas in the vapor distribution plenum 32 before the process gas passes through the vapor distribution plate 34 into the processing zone 33. Alternately, the dilution gas source 37 can be coupled to the process chamber 10 via feed line 37b and configured to add the dilution gas to the process gas in the processing zone 33 above the substrate 25 after the process gas passes through the vapor distribution plate 34. Still alternately, the dilution gas source 37 can be coupled to the vapor distribution system 30 via feed line 37c and configured to add the dilution gas to the process gas in the distribution plate 34. As will be appreciated by those skilled in the art, the dilution gas can be added to the process gas at other locations in the vapor distribution system 30 and the process chamber 10 without departing from the scope of the invention.

In yet another embodiment, the dilution gas is introduced to the process gas from the dilution gas source 37 through one of feed lines 37a, 37b, 37c, or other feed lines (not shown) in such a way that the concentration of dilution gas at one region above substrate 25 can be adjusted to be different than the concentration of dilution gas at another region above substrate 25. For example, the flow of dilution gas to a central region of substrate 25 can be different than the flow of dilution gas to a peripheral region of substrate 25.

Once film precursor vapor enters the processing zone 33, the film precursor vapor thermally decomposes upon adsorption at the substrate surface due to the elevated temperature of the substrate 25, and the thin film is formed on the substrate 25. The substrate holder 20 is configured to elevate the temperature of substrate 25 by virtue of the substrate holder 20 being coupled to a substrate temperature control system 22. For example, the substrate temperature control system 22 can be configured to elevate the temperature of substrate 25 up to approximately 500° C. In one embodiment, the substrate temperature can range from about 100° C. to about 500° C. In another embodiment, the substrate temperature can range from about 150° C. to about 350° C. Additionally, process chamber 10 can be coupled to a chamber temperature control system 12 configured to control the temperature of the chamber walls.

As described above, for example, conventional systems have contemplated operating the film precursor vaporization system 50, as well as the vapor delivery system 40, within a temperature range of approximately 40-45° C. for ruthenium carbonyl in order to limit metal vapor precursor decomposition and metal vapor precursor condensation. For example, the ruthenium carbonyl precursor can decompose at elevated temperatures to form by-products, such as those illustrated below:
Ru₃(CO)₁₂*(ad) [symbol] Ru₃(CO)ₓ*(ad)+(12−x)CO(g) (1)
or,
Ru₃(CO)ₓ*(ad) [symbol] 3Ru(s)+xCO(g) (2)
wherein these by-products can adsorb (ad), i.e., condense, on the interior surfaces of the deposition system 1. The accumulation of material on these surfaces can cause problems from one substrate to the next, such as process repeatability. Alternatively, for example, the ruthenium carbonyl precursor can condense at depressed temperatures to cause recrystallization, viz.
Ru₃(CO)₁₂(g) [symbol] Ru₃(CO)₁₂*(ad) (3).

In summary, the low vapor pressure of some metal carbonyl precursors (e.g., Ru₃(CO)₁₂) and the small process window result in a very low deposition rate of a metal layer on the substrate 25.

Adding a CO gas to the metal carbonyl precursor vapor can reduce the above-mentioned problems that limit the delivery of the metal carbonyl precursor to the substrate. Thus, according to an embodiment of the invention, the CO gas is added to the metal carbonyl precursor vapor to reduce dissociation of the metal carbonyl precursor vapor in the gas line, thereby shifting the equilibrium in Equation (1) to the left and reducing premature decomposition of the metal carbonyl precursor in the vapor precursor delivery system 40 prior to delivery of the metal carbonyl precursor to the process chamber 10. It is believed that addition of the CO gas to the metal carbonyl precursor vapor allows for increasing the vaporization temperature from approximately 40° C. to approximately 150° C., or higher. The elevated temperature increases the vapor pressure of the metal carbonyl precursor, resulting in increased delivery of the metal carbonyl precursor to the process chamber and, hence, increased deposition rate of the metal on the substrate 25. Furthermore, it has been visually observed that flowing a mixture of an inert gas, such as Ar, and the CO gas over or through the metal carbonyl precursor reduces premature decomposition of the metal carbonyl precursor.

According to an embodiment of the invention, the addition of CO gas to a Ru₃(CO)₁₂ precursor vapor allows for maintaining the Ru₃(CO)₁₂ precursor vaporization temperature from approximately 40° C. to approximately 150° C. Alternately, the vaporization temperature can be maintained at approximately 60° C. to approximately 90° C.

Thermal decomposition of metal carbonyl precursors and subsequent metal deposition on the substrate 25 is thought to proceed predominantly by CO elimination and desorption of CO by-products from the substrate 25. Incorporation of CO by-products into the metal layers during deposition can result from incomplete decomposition of the metal carbonyl precursor, incomplete removal of CO by-products from the metal layer, and re-adsorption of CO by-products from the process chamber 10 onto the metal layer.

It is believed that CO incorporation into a metal layer during deposition leads to surface roughness in the form of nodules in the metal layer, where the growth of nodules is enhanced by increased incorporation of CO by-products into the metal layer. The number of nodules is expected to increase as the thickness of the metal layer increases. Furthermore, the incorporation of CO by-products into the metal layer increases the resistivity of the metal layer.

Incorporation of CO by-products into the metal layer can be reduced by (1) lowering the process pressure, and (2) increasing the substrate temperature. In accordance with the present invention, it has been realized that the above-mentioned problems can also be reduced by adding a dilution gas in the process chamber 10 to the process gas containing the metal carbonyl precursor vapor and the CO gas for controlling and reducing the partial pressure of by-products and the CO gas in the process chamber. Thus, according to an embodiment of the invention, a dilution gas from dilution gas source 37 is added to the process gas for controlling and reducing the partial pressure of CO by-products on the metal layer and the partial pressure of CO in the process chamber 10, thereby forming a smooth metal layer. The dilution gas can include, for example, an inert gas, such as a noble gas, He, Ne, Ar, Kr, or Xe, or a mixture of two or more thereof. The dilution gas may further contain a reducing gas to improve the material properties of the metal layer, for example the electrical resistivity. The reducing gas can, for example, contain H₂, a silicon-containing gas (e.g., SiH₄, Si₂H₆, or SiCl₂H₂), a boron-containing gas (e.g., BH₃, B₂H₆, or B₃H₉), or a nitrogen-containing gas (e.g., NH₃). According to an embodiment of the invention, the process chamber pressure can be between about 0.1 mTorr and about 200 mTorr. Alternately, the process chamber pressure can be between about 1 mTorr and about 100 mTorr. Still alternately, the process chamber pressure can be between about 2 mTorr and about 50 mTorr.

Since the addition of the CO gas to the metal carbonyl precursor vapor increases the thermal stability of the metal carbonyl precursor vapor, the relative concentration of the metal carbonyl precursor vapor to the CO gas in the process gas can be utilized to control the decomposition rate of the metal carbonyl precursor on the substrate 25 at a certain substrate temperature. Furthermore, the substrate temperature can be utilized to control the decomposition rate (and thereby the deposition rate) of the metal on the substrate 25. As those skilled in the art will readily appreciate, the amount of CO gas and the substrate temperature can easily be varied to allow for a desired vaporization temperature of the metal carbonyl precursor and for achieving a desired deposition rate of the metal carbonyl precursor on the substrate 25.

Furthermore, the amount of CO gas in the process gas can be selected so that metal deposition on the substrate 25 from a metal carbonyl precursor occurs in a kinetic-limited temperature regime. For example, the amount of CO gas in the process gas can be increased until the metal deposition process is observed to occur in a kinetic-limited temperature regime. A kinetic-limited temperature regime refers to the range of deposition conditions where the deposition rate of a chemical vapor deposition process is limited by the kinetics of the chemical reactions at the substrate surface, typically characterized by a strong dependence of deposition rate on temperature. Unlike the kinetic-limited temperature regime, a mass-transfer limited regime is normally observed at higher substrate temperatures and includes a range of deposition conditions where the deposition rate is limited by the flux of chemical reactants to the substrate surface. A mass-transfer limited regime is characterized by a strong dependence of deposition rate on metal carbonyl precursor flow rate and is independent of deposition temperature. Metal deposition in the kinetic-limited regime normally results in good step coverage and good conformality of the metal layer on patterned substrates. Conformality is commonly defined as the thinnest part of the metal layer on the sidewall of a feature on the patterned substrate divided by the thickest part of the metal layer on the sidewall. Step coverage is commonly defined as the sidewall coverage (metal layer thickness on sidewall divided by the metal layer thickness away from the feature) divided by the bottom coverage (metal layer thickness on the bottom of the feature divided by the metal layer thickness away from the feature).

Additionally, in accordance with the present invention, it is observed that the stability of film deposition and the resultant properties of the deposited film can be affected by variations in the flow of CO gas and precursor vapor to the deposition system. For example, during the initial introduction of CO gas and precursor vapor to the deposition system, flow variations may occur until the flow rate stabilizes through the metal precursor vaporization system, the vapor delivery system, and the vapor distribution system. According to one embodiment, as will be described later, a flow of process gas containing CO and precursor vapor is established prior to introducing the process gas to the deposition system within which the substrate is held. Once the flow rate of process gas stabilizes over a period of time, then the process gas is introduced to the deposition system.

Still referring to FIG. 1, optionally, the deposition system 1 can be periodically cleaned using an in-situ cleaning system 70 coupled to, for example, the vapor delivery system 40, as shown in FIG. 1. Per a frequency determined by the operator, the in-situ cleaning system 70 can perform routine cleanings of the deposition system 1 in order to remove accumulated residue on internal surfaces of deposition system 1. The in-situ cleaning system 70 can, for example, comprise a radical generator configured to introduce chemical radical capable of chemically reacting and removing such residue. Additionally, for example, the in-situ cleaning system 70 can, for example, include an ozone generator configured to introduce a partial pressure of ozone. For instance, the radical generator can include an upstream plasma source configured to generate oxygen or fluorine radical from oxygen (O₂), nitrogen trifluoride (NF₃), O₃, XeF₂, ClF₃, or C₃F₈ (or, more generally, CₓF_{y}), respectively. The radical generator can include an ASTRON® reactive gas generator, commercially available from MKS Instruments, Inc., ASTeX® Products (90 Industrial Way, Wilmington, Mass. 01887).

Still referring the FIG. 1, the deposition system 1 can further include a control system 80 configured to operate and control the operation of the deposition system 1. The control system 80 is coupled to the process chamber 10, the substrate holder 20, the substrate temperature control system 22, the chamber temperature control system 12, the vapor distribution system 30, the vapor delivery system 40, the film precursor vaporization system 50, the carrier gas supply system 60, the dilution gas source 37, and the optional in-situ cleaning system 70.

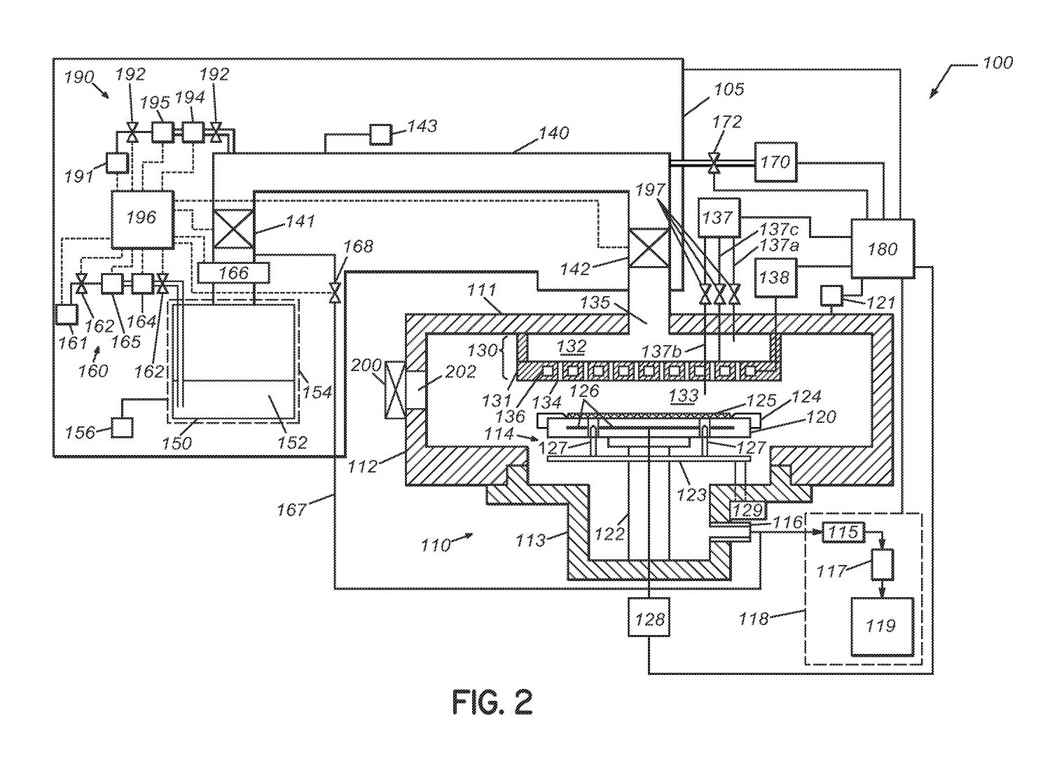

In another embodiment, FIG. 2 illustrates a deposition system 100 for depositing a metal film, such as a ruthenium (Ru) film, on a substrate. The deposition system 100 comprises a process chamber 110 having a substrate holder 120 configured to support a substrate 125 upon which the metal layer is formed. The process chamber 110 is coupled to a precursor delivery system 105 having metal precursor vaporization system 150 configured to store and evaporate a metal carbonyl precursor 152, and a vapor precursor delivery system 140 configured to transport the metal carbonyl precursor 152 to the process chamber 110.

The process chamber 110 comprises an upper chamber section 111, a lower chamber section 112, and an exhaust chamber 113. An opening 114 is formed within lower chamber section 112, where bottom section 112 couples with exhaust chamber 113.

Referring still to FIG. 2, substrate holder 120 provides a horizontal surface to support substrate (or wafer) 125, which is to be processed. The substrate holder 120 can be supported by a cylindrical support member 122, which extends upward from the lower portion of exhaust chamber 113. A shield ring 124 for reducing CO poisoning on the substrate 125 on the substrate holder 120 is provided on the edge of substrate holder 120. Furthermore, the substrate holder 120 comprises a heater 126 coupled to substrate holder temperature control system 128. The heater 126 can, for example, include one or more resistive heating elements. Alternately, the heater 126 can, for example, include a radiant heating system, such as a tungsten-halogen lamp. The substrate holder temperature control system 128 can include a power source for providing power to the one or more heating elements, one or more temperature sensors for measuring the substrate temperature or the substrate holder temperature, or both, and a controller configured to perform at least one of monitoring, adjusting, or controlling the temperature of the substrate 125 or substrate holder 120.

During processing, the heated substrate 125 can thermally decompose the metal carbonyl precursor vapor, and enable deposition of a metal layer on the substrate 125. According to an embodiment, the metal carbonyl precursor 152 can be a ruthenium carbonyl precursor, for example Ru₃(CO)₁₂. As will be appreciated by those skilled in the art of thermal chemical vapor deposition, other metal carbonyl precursors and other ruthenium carbonyl precursors can be used without departing from the scope of the invention. The substrate holder 120 is heated to a pre-determined temperature that is suitable for depositing the desired Ru metal layer or other metal layer onto the substrate 125. Additionally, a heater (not shown) coupled to a chamber temperature control system 121 can be embedded in the walls of process chamber 110 to heat the chamber walls to a pre-determined temperature. The heater can maintain the temperature of the walls of process chamber 110 from about 40° C. to about 150° C., or from about 40° C. to about 80° C. A pressure gauge (not shown) is used to measure the process chamber pressure. According to an embodiment of the invention, the process chamber pressure can be between about 0.1 mTorr and about 200 mTorr. Alternately, the process chamber pressure can be between about 1 mTorr and about 100 mTorr. Still alternately, the process chamber pressure can be between about 2 mTorr and about 50 mTorr.

Also shown in FIG. 2, a vapor distribution system 130 is coupled to the upper chamber section 111 of process chamber 110. Vapor distribution system 130 comprises a vapor distribution plate 131 configured to introduce precursor vapor from vapor distribution plenum 132 to a processing zone 133 above substrate 125 through one or more orifices 134.

According to an embodiment of the invention, a dilution gas source 137 is coupled to the process chamber 110 and is configured to add a dilution gas to dilute the process gas containing the metal carbonyl precursor vapor and the CO gas using feed lines 137a, 137b, and/or 137c, valves 197, one or more filters (not shown), and a mass flow controller (not shown). As shown in FIG. 2, the dilution gas source 137 can be coupled to the vapor distribution system 130 of process chamber 110 and is configured to add the dilution gas to the process gas in the vapor distribution plenum 132 via feed line 137a before the process gas passes through the vapor distribution plate 131 into the processing zone 133 above the substrate 125, or the dilution gas source 137 can be configured to add the dilution gas to the process gas inside the vapor distribution plate 131 via feed line 137c. Alternately, the dilution gas source 137 can be coupled to the process chamber 110 and is configured to add the dilution gas to the process gas in the processing zone 133 via feed line 137b after the process gas passes through the vapor distribution plate 131. As will be appreciated by those skilled in the art, the dilution gas can be added to the process gas at other locations in the process chamber 110 without departing from the scope of the invention.

In yet another embodiment, the dilution gas is introduced to the process gas from the dilution gas source 137 through one of feed lines 137a, 137b, 137c, or other feed lines (not shown) in such a way that the concentration of dilution gas at one region above substrate 125 can be adjusted to be different than the concentration of dilution gas at another region above substrate 125. For example, the flow of dilution gas to a central region of substrate 125 can be different than the flow of dilution gas to a peripheral region of substrate 125.

Furthermore, an opening 135 is provided in the upper chamber section 111 for introducing a metal carbonyl precursor vapor from vapor precursor delivery system 140 into vapor distribution plenum 132. Moreover, temperature control elements 136, such as concentric fluid channels configured to flow a cooled or heated fluid, are provided for controlling the temperature of the vapor distribution system 130, and thereby prevent the decomposition or condensation of the metal carbonyl precursor inside the vapor distribution system 130. For instance, a fluid, such as water, can be supplied to the fluid channels from a vapor distribution temperature control system 138. The vapor distribution temperature control system 138 can include a fluid source, a heat exchanger, one or more temperature sensors for measuring the fluid temperature or vapor distribution plate temperature or both, and a controller configured to control the temperature of the vapor distribution plate 131 from about 20° C. to about 150° C.

As illustrated in FIG. 2, a metal precursor vaporization system 150 is configured to hold a metal carbonyl precursor 152 and evaporate (or sublime) the metal carbonyl precursor 152 by elevating the temperature of the metal carbonyl precursor. A precursor heater 154 is provided for heating the metal carbonyl precursor 152 to maintain the metal carbonyl precursor 152 at a temperature that produces a desired vapor pressure of metal carbonyl precursor 152. The precursor heater 154 is coupled to a vaporization temperature control system 156 configured to control the temperature of the metal carbonyl precursor 152. For example, the precursor heater 154 can be configured to adjust the temperature of the metal carbonyl precursor 152 from about 40° C. to about 150° C., or from about 60° C. to about 90° C.

As the metal carbonyl precursor 152 is heated to cause evaporation (or sublimation), a carrier gas can be passed over or through the metal carbonyl precursor 152, or any combination thereof. The carrier gas can include, for example, an inert gas, such as a noble gas (i.e., He, Ne, Ar, Kr, Xe). Alternately, other embodiments contemplate omitting the inert carrier gas. According to an embodiment of the invention, a CO gas can be added to the inert carrier gas. Alternately, other embodiments contemplate the CO gas replacing the inert carrier gas. For example, a gas supply system 160 is coupled to the metal precursor vaporization system 150, and it is configured to, for instance, flow the carrier gas, the CO gas, or both, over or through the metal carbonyl precursor 152. Although not shown in FIG. 2, gas supply system 160 can also or alternatively be coupled to the vapor precursor delivery system 140 to supply the CO gas and optional inert carrier gas to the vapor of the metal precursor 152 as or after it enters the vapor precursor delivery system 140. The gas supply system 160 can comprise a gas source 161 containing an inert carrier gas, a CO gas, or a mixture thereof, one or more control valves 162, one or more filters 164, and a mass flow controller 165. For instance, the mass flow rate of inert carrier gas or the CO gas can range from approximately 0.1 sccm to approximately 1000 sccm.

Additionally, a sensor 166 is provided for measuring the total gas flow from the metal precursor vaporization system 150. The sensor 166 can, for example, comprise a mass flow controller, and the amount of metal carbonyl precursor vapor delivered to the process chamber 110 can be determined using sensor 166 and mass flow controller 165. Alternately, the sensor 166 can comprise a light absorption sensor to measure the concentration of the metal carbonyl precursor in the gas flow to the process chamber 110.

A bypass line 167 can be located downstream from sensor 166, and it can connect the vapor delivery system 140 to an exhaust line 116. Bypass line 167 is provided for evacuating the vapor precursor delivery system 140, and for stabilizing the supply of the metal carbonyl precursor to the process chamber 110. In addition, a bypass valve 168, located downstream from the branching of the vapor precursor delivery system 140, is provided on bypass line 167.

Referring still to FIG. 2, the vapor precursor delivery system 140 comprises a high conductance vapor line having first and second valves 141 and 142, respectively. Additionally, the vapor precursor delivery system 140 can further comprise a vapor line temperature control system 143 configured to heat the vapor precursor delivery system 140 via heaters (not shown). The temperatures of the vapor lines can be controlled to avoid condensation of the metal carbonyl precursor vapor in the vapor line. The temperature of the vapor lines can be controlled from about 20° C. to about 100° C., or from about 40° C. to about 90° C.

Moreover, a CO gas can be supplied from a gas supply system 190. For example, the gas supply system 190 is coupled to the vapor precursor delivery system 140, and it is configured to, for instance, mix the CO gas with the metal carbonyl precursor vapor in the vapor precursor delivery system, for example, downstream of valve 141. The gas supply system 190 can comprise a CO gas source 191, one or more control valves 192, one or more filters 194, and a mass flow controller 195. For instance, the mass flow rate of CO gas can range from approximately 0.1 sccm to approximately 1000 sccm.

Mass flow controllers 165 and 195, and valves 162, 192, 168, 141, and 142 are controlled by controller 196, which controls the supply, shutoff, and the flow of the inert carrier gas, the CO gas, and the metal carbonyl precursor vapor. Sensor 166 is also connected to controller 196 and, based on output of the sensor 166, controller 196 can control the carrier gas flow through mass flow controller 165 to obtain the desired metal carbonyl precursor flow to the process chamber 110.

Furthermore, as described above, and as shown in FIG. 2, an optional in-situ cleaning system 170 is coupled to the precursor delivery system 105 of deposition system 100 through cleaning valve 172. For instance, the in-situ cleaning system 170 can be coupled to the vapor delivery system 140. The in-situ cleaning system 170 can, for example, comprise a radical generator configured to introduce chemical radical capable of chemically reacting and removing such residue. Additionally, for example, the in-situ cleaning system 170 can, for example, include an ozone generator configured to introduce a partial pressure of ozone. For instance, the radical generator can include an upstream plasma source configured to generate oxygen or fluorine radical from oxygen (O₂), nitrogen trifluoride (NF₃), ClF₃, O₃, XeF₂, or C₃F₈ (or, more generally, CₓF_{y}), respectively. The radical generator can include an ASTRON® reactive gas generator, commercially available from MKS Instruments, Inc., ASTeX® Products (90 Industrial Way, Wilmington, Mass. 01887).

As illustrated in FIG. 2, the exhaust line 116 connects exhaust chamber 113 to pumping system 118. A vacuum pump 119 is used to evacuate process chamber 110 to the desired degree of vacuum, and to remove gaseous species from the process chamber 110 during processing. An automatic pressure controller (APC) 115 and a trap 117 can be used in series with the vacuum pump 119. The vacuum pump 119 can include a turbo-molecular pump (TMP) capable of a pumping speed up to 500 liters per second (and greater). Alternately, the vacuum pump 119 can include a dry roughing pump. During processing, the process gas can be introduced into the process chamber 110, and the chamber pressure can be adjusted by the APC 115. The APC 115 can comprise a butterfly-type valve or a gate valve. The trap 117 can collect unreacted metal carbonyl precursor material and by-products from the process chamber 110.

Referring back to the substrate holder 120 in the process chamber 110, as shown in FIG. 2, three substrate lift pins 127 (only two are shown) are provided for holding, raising, and lowering the substrate 125. The substrate lift pins 127 are coupled to plate 123, and can be lowered to below to the upper surface of substrate holder 120. A drive mechanism 129 utilizing, for example, an air cylinder provides means for raising and lowering the plate 123. Substrate 125 can be transferred into and out of process chamber 110 through gate valve 200 and chamber feed-through passage 202 via a robotic transfer system (not shown), and received by the substrate lift pins 127. Once the substrate 125 is received from the transfer system, it can be lowered to the upper surface of the substrate holder 120 by lowering the substrate lift pins 127.

Referring again to FIG. 2, a controller 180 includes a microprocessor, a memory, and a digital I/O port capable of generating control voltages sufficient to communicate and activate inputs of the processing system 100 as well as monitor outputs from the processing system 100. Moreover, the processing system controller 180 is coupled to and exchanges information with process chamber 110; precursor delivery system 105, which includes controller 196, vapor line temperature control system 143, metal precursor vaporization system 150, gas supply system 190, gas supply system 160, and vaporization temperature control system 156; vapor distribution temperature control system 138; dilution gas source 137; vacuum pumping system 118; and substrate holder temperature control system 128. In the vacuum pumping system 118, the controller 180 is coupled to and exchanges information with the automatic pressure controller 115 for controlling the pressure in the process chamber 110. A program stored in the memory is utilized to control the aforementioned components of deposition system 100 according to a stored process recipe. One example of processing system controller 180 is a DELL PRECISION WORKSTATION 610™, available from Dell Corporation, Dallas, Tex. The controller 180 may also be implemented as a general-purpose computer, digital signal process, etc.

Controller 180 may be locally located relative to the deposition system 100, or it may be remotely located relative to the deposition system 100 via the internet or an intranet. Thus, controller 180 can exchange data with the deposition system 100 using at least one of a direct connection, an intranet, or the internet. Controller 180 may be coupled to an intranet at a customer site (i.e., a device maker, etc.), or coupled to an intranet at a vendor site (i.e., an equipment manufacturer). Furthermore, another computer (i.e., controller, server, etc.) can access controller 180 to exchange data via at least one of a direct connection, an intranet, or the internet.

As described above, it is observed that the stability of film deposition and the resultant properties of the deposited film can be affected by variations in the flow of CO gas and precursor vapor to the deposition system. For example, during the initial introduction of CO gas and precursor vapor to the deposition system, flow variations may occur until the flow rate stabilizes through the metal precursor vaporization system, the vapor delivery system, and the vapor distribution system. According to one embodiment, a flow of process gas containing CO and precursor vapor is established prior to introducing the process gas to the deposition system within which the substrate is held. Once the flow rate of process gas stabilizes over a period of time, then the process gas is introduced to the deposition system.

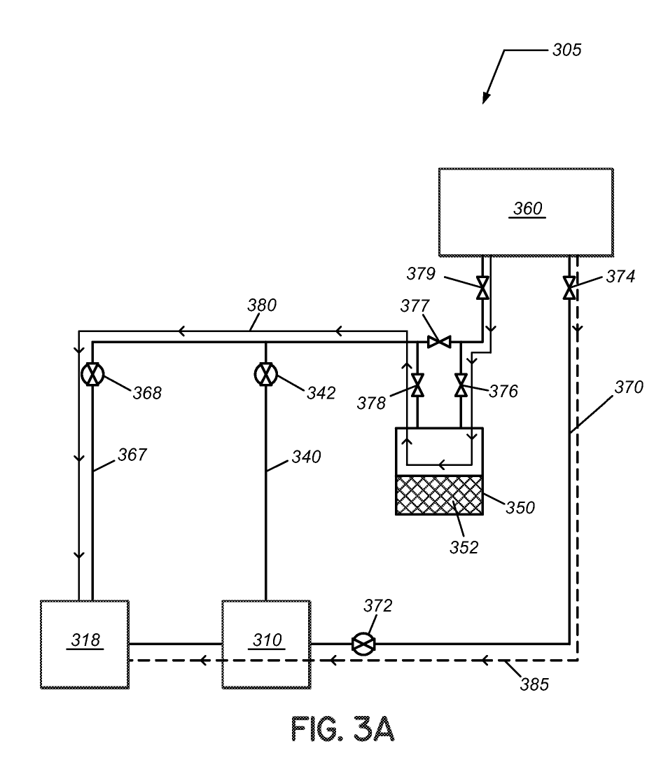

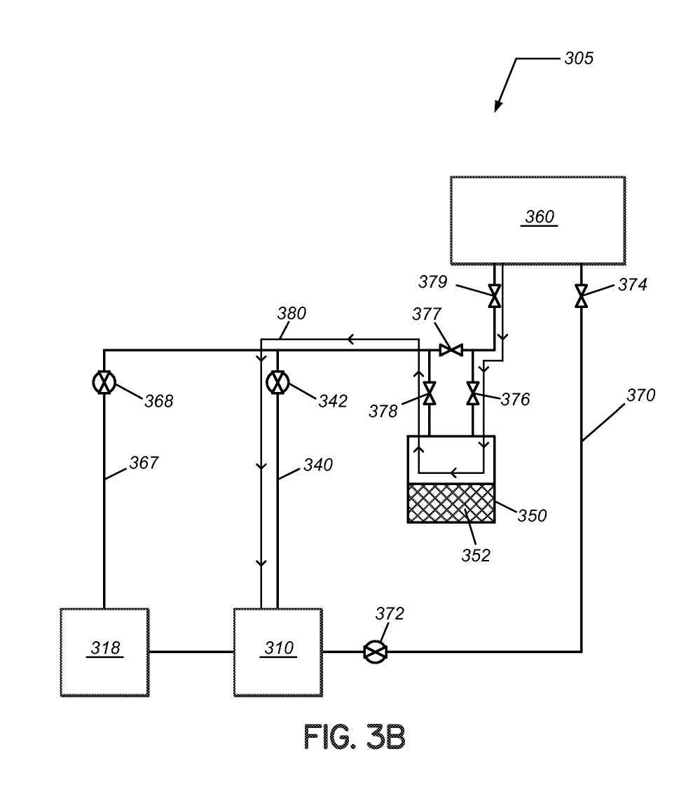

Referring now to FIGS. 3A and 3B, a vapor supply system 305 for initiating the introduction of a metal carbonyl precursor vapor to a deposition system 310 is described according to one embodiment. As illustrated in FIG. 3A, a (pre-process) flow 380 of process gas containing precursor vapor with a CO gas and an optional inert carrier gas is established, whereby the CO gas and the optional carrier gas originate from gas supply system 360 through valve 379, entrain precursor vapor originating from a metal precursor vaporization system 350 containing precursor 352, and flow through a bypass line 367 to an evacuation system 318. The precursor 352 can include a solid precursor, and may include a metal carbonyl precursor, such as any one of the precursors described above. As described above, the gas supply system 360 can include a carrier gas source, a CO gas source, a purge gas source, one or more control valves, one or more filters, one or more flow conditioning devices, and one or more mass flow controllers for introducing process gas flow 380 to a deposition system 310.

When introducing or delivering a metal carbonyl precursor vapor to the deposition system 310, the delivery gas contains CO gas and optionally an inert carrier gas, such as a noble gas. The CO gas and the optional carrier gas may pass over or through precursor 352 by flowing through valve 376 (when open), through the metal precursor vaporization system 350, and through valve 378. Alternatively, the CO gas and optional carrier gas may entrain precursor vapor downstream of the metal precursor vaporization system 350 by passing through valve 377 (when open).

Prior to introducing the process gas to the deposition system 310, a first flow control valve 342 remains closed, while a second flow control valve 368 is opened, thus permitting the flow 380 of process gas through the bypass line 367 to the evacuation system 318. The evacuation system may be independent from the evacuation system coupled to the deposition system, or it may be the same.

While the flow 380 of process gas is established to the evacuation system 318, an additional flow 385 of purge gas can be introduced through purge line 370, valve 374 and a third flow control valve 372 to deposition system 310. The purge gas can include an inert gas, such as a noble gas, or CO gas, or a mixture thereof. The flow 385 of purge gas is optional, as indicated by dashed line in FIG. 3A.

After a duration of time, and once the flow rate of process gas stabilizes in the bypass line 367, the second flow control valve 368 is closed, and the first flow control valve 342 is opened, hence, permitting the introduction of the flow 380 of process gas through vapor delivery line 340 to deposition system 310, as illustrated in FIG. 3B. Furthermore, the additional flow 385 of purge gas to deposition system 310 is terminated by closing the third flow control valve 372. The flow 385 of purge gas can be terminated prior to introducing the flow 380 of process gas to the deposition system 310, i.e., the third flow control valve 372 is closed before the first flow control valve 342 is opened. Alternately, the flow 385 of purge gas can be terminated concurrently with the introduction of the flow 380 of process gas to the deposition system 310, i.e., the third flow control valve 372 is closed at the same time that the first flow control valve 342 is opened.

The time duration can, as suggested above, comprise a time period sufficiently long to stabilize the flow rate of process gas to the evacuation system 318. The time duration can, for example, range from approximately 1 second to approximately 20 seconds, and desirably, for example, the time duration can range from approximately 2 seconds to approximately 10 seconds. For instance, the time duration can be approximately 5 seconds.

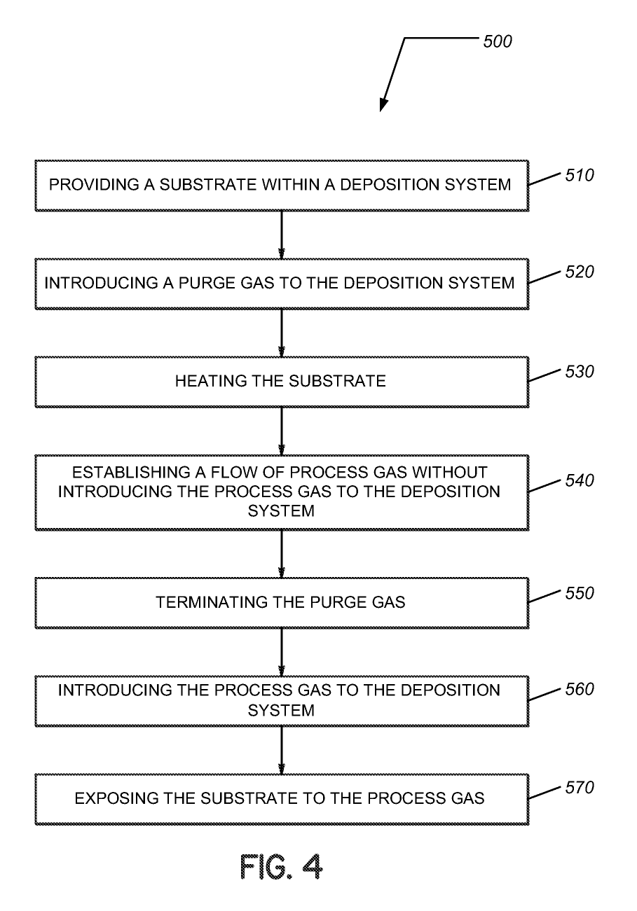

Referring now to FIG. 4, a method of depositing a metal layer on a substrate is illustrated according to an embodiment of the invention. The method 500 includes, at 510, providing a substrate within a process space in a process chamber of a deposition system. For example, the deposition system can include the depositions systems described above in FIGS. 1 and 2. The substrate can, for example, be a Si substrate. A Si substrate can be of n- or p-type, depending on the type of device being formed. The substrate can be of any size, for example a 200 mm substrate, a 300 mm substrate, or an even larger substrate. According to an embodiment of the invention, the substrate can be a patterned substrate containing one or more vias or trenches, or combinations thereof.

At 520, a flow of purge gas is introduced to the process chamber. The purge gas can, as described above, include an inert gas, such as a noble gas, or CO, or a mixture thereof. At 530, the substrate is elevated in temperature to a deposition temperature adequate for a thermal chemical vapor deposition (CVD) process. For example, the deposition temperature can range up to approximately 500° C. In one embodiment, the deposition temperature can range from about 100° C. to about 500° C. In another embodiment, the deposition temperature can range from about 150° C. to about 350° C.

The flow of purge gas may occur before, during, or after the heating of the substrate. For example, in order to decrease the time required to reach the desired substrate temperature (for a given input power), the background pressure of purge gas can be increased. The background pressure can, for instance, be set to a value greater than or equal to approximately 0.1 torr, and desirably, for instance, the background pressure can be set to a value greater than or equal to approximately 0.5 torr. Further yet, the background pressure of the purge gas can be set to approximately 1 torr or greater. In the case where the substrate rests on the substrate holder (without substrate clamping), the increase in background pressure improves the thermal conductance between the substrate and the substrate holder.

At 540, a flow of process gas containing a metal carbonyl precursor vapor and a CO gas is established without introducing the flow of process gas to the process chamber. As discussed above, the flow may be established through a bypass line to an evacuation system. The flow of process gas in 540 can be established concurrently with heating of the substrate in 530 and purging of the deposition system in 520, or the flow can be established sequentially after the substrate has been heated and the chamber purged.

The process gas can further contain a carrier gas. As described above, according to one embodiment, the metal carbonyl precursor can be a ruthenium carbonyl precursor, for example Ru₃(CO)₁₂. Addition of the CO gas to the metal carbonyl precursor vapor allows for increasing the vaporization temperature of the metal carbonyl precursor. The elevated temperature increases the vapor pressure of the metal carbonyl precursor, resulting in increased delivery of the metal carbonyl precursor vapor to the process chamber and, hence, increased deposition rate of the metal on a substrate.

The process gas can be formed by heating the metal carbonyl precursor to form the metal carbonyl precursor vapor, and mixing the CO gas with the metal carbonyl precursor vapor. For instance, the CO gas can be mixed with the metal carbonyl precursor vapor downstream from the metal carbonyl precursor. Alternatively, for instance, the CO gas can be mixed with the metal carbonyl precursor vapor by flowing the CO gas over or through the metal carbonyl precursor. Alternatively yet, for instance, the process gas can be formed by additionally flowing a carrier gas over or through the solid metal carbonyl precursor.

At 550, the flow of purge gas to the process chamber is terminated. As discussed above, the flow of purge gas to the process chamber is optional, such that steps 520 and 550 are optional.

At 560, once the flow of process gas is established at a stable rate, and after or while the flow of purge gas is terminated, the process gas is introduced to the process chamber containing the heated substrate. For example, the process gas is transported to a vapor distribution plenum, from which the process gas is distributed and introduced to the process space adjacent the substrate. At 570, the heated substrate is exposed to the process gas to deposit a metal layer on the substrate by a thermal chemical vapor deposition process.

As would be appreciated by those skilled in the art, each of the steps or stages in the flowchart of FIG. 4 may encompass one or more separate steps and/or operations. Accordingly, the recitation of only seven steps in 510, 520, 530, 540, 550, 560, and 570 should not be understood to limit the method of the present invention solely to seven steps or stages. Moreover, each representative step or stage 510, 520, 530, 540, 550, 560, 570 should not be understood to be limited to only a single process.

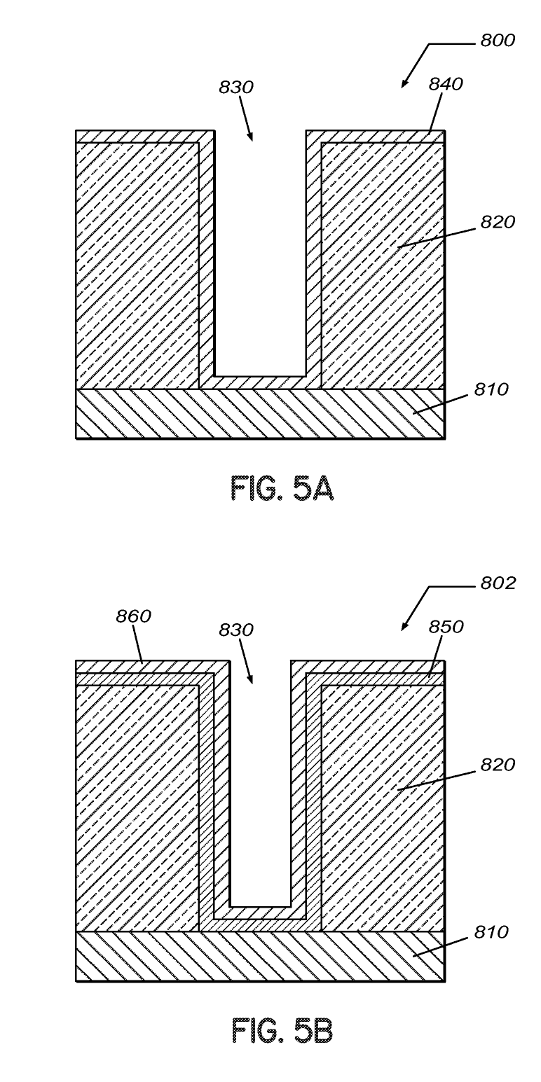

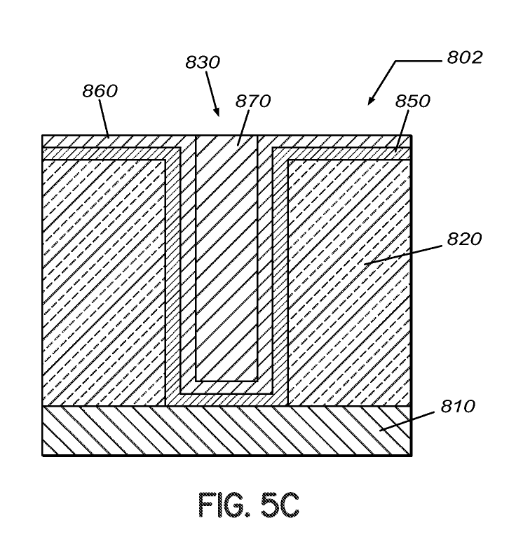

FIGS. 5A through 5C schematically show formation of a metal layer on a patterned substrate according to embodiments of the invention. As those skilled in the art will readily appreciate, embodiments of the invention can be applied to patterned substrates containing one or more vias or trenches, or combinations thereof. FIG. 5A schematically shows deposition of a metal layer 840 onto a patterned structure 800 according to an embodiment of the invention. The patterned structure 800 contains a first metal layer 810, and a patterned layer 820 containing an opening 830. The patterned layer 820 can, for example, be a dielectric material. The opening 830 can, for example, be a via or a trench, and the metal layer 840 can, for example, contain Ru metal.

FIG. 5B schematically shows deposition of a metal layer 860 onto a patterned structure 802 according to another embodiment of the invention. The patterned structure 802 contains a first metal layer 810 and a patterned layer 820 containing an opening 830. A barrier layer 850 is deposited onto the patterned structure 802, and a metal layer 860 is deposited on the barrier layer 850. The barrier layer 850 can, for example, contain a tantalum-containing material (e.g., Ta, TaN, or TaCN, or a combination of two or more thereof) or a tungsten material (e.g., W, WN). The patterned layer 820 can, for example, be a dielectric material. The opening 830 can, for example, be a via or a trench, and the metal layer 860 can, for example, contain Ru metal. FIG. 5C schematically shows deposition of Cu in the opening 830 of FIG. 5B.

The metal layers 840 and 860 may be deposited, as described above, using a process gas comprising a metal carbonyl precursor, for example a ruthenium carbonyl, and carbon monoxide (CO). An initial flow of the process gas is first established for a period of time to achieve a steady flow rate before introduction to the deposition chamber. The steady flow of the process gas is then introduced into the chamber for deposition of the metal layer 840 or 860 onto the patterned structure 800 or 802.

Although only certain exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

What is claimed is:

1. A method of depositing a metal layer on a substrate, the method comprising:
providing a substrate within a deposition system;
heating said substrate in said deposition system to a deposition temperature;
establishing a flow of process gas containing a metal carbonyl precursor vapor and a CO gas to an exhaust system without introducing said flow of process gas to said deposition system for a duration of time;
after said duration of time, introducing said flow of process gas to said deposition system; and
exposing said substrate at said deposition temperature to said process gas to deposit a metal layer on said substrate by a vapor deposition process.

2. The method of claim 1, wherein said heating said substrate to said deposition temperature comprises heating said substrate to a temperature ranging between about 50° C. and about 500° C.

3. The method of claim 1, wherein said heating said substrate to said deposition temperature comprises heating said substrate to a temperature ranging between about 150° C. and about 350° C.

4. The method of claim 1, wherein said establishing said flow of process gas comprises:
heating a metal carbonyl precursor to form said metal carbonyl precursor vapor; and
mixing said CO gas with said metal carbonyl precursor vapor downstream from said metal carbonyl precursor.

5. The method of claim 1, wherein said establishing said flow of process gas comprises:
heating a metal carbonyl precursor to form said metal carbonyl precursor vapor while flowing said CO gas over or through said metal carbonyl precursor.

6. The method of claim 1, wherein said process gas further comprises an inert carrier gas.

7. The method of claim 6, wherein said inert carrier gas comprises a noble gas.

8. The method of claim 1, further comprising maintaining said process chamber at a pressure between about 0.1 mTorr and about 200 mTorr during said exposing.

9. The method of claim 1, further comprising:
introducing a flow of purge gas to said deposition system; and
terminating said flow of purge gas prior to or concurrently with said introducing said flow of process gas to said deposition system.

10. The method of claim 9, wherein said introducing said purge gas comprises introducing a noble gas, or CO gas, or a mixture thereof, to said deposition system.

11. The method of claim 9, wherein said introducing said purge gas comprises introducing a purge gas during said heating of said substrate and maintaining a pressure within said deposition system above about 0.1 torr in order to increase a heating rate of said substrate.

12. The method of claim 9, wherein said introducing said purge gas comprises introducing a purge gas during said heating of said substrate and maintaining a pressure within said deposition system above about 1 torr in order to increase a heating rate of said substrate.

13. The method of claim 1, wherein said metal carbonyl precursor vapor comprises a tungsten carbonyl, a molybdenum carbonyl, a cobalt carbonyl, a rhodium carbonyl, a rhenium carbonyl, a chromium carbonyl, a ruthenium carbonyl, or an osmium carbonyl, or a combination of two or more thereof.

14. The method of claim 1, wherein said metal carbonyl precursor vapor comprises W(CO)₆, Mo(CO)₆, Co₂(CO)₈, Rh₄(CO)₁₂, Re₂(CO)₁₀, Cr(CO)₆, Ru₃(CO)₁₂, or Os₃(CO)₁₂, or a combination of two or more thereof.

15. The method of claim 1, where said duration of time is of sufficient length to create a stable flow rate of said process gas.

16. The method of claim 1, wherein said duration of time is approximately 1 second to approximately 20 seconds.

17. The method of claim 1, wherein said duration of time is approximately 2 seconds to approximately 10 seconds.

18. A method of depositing a ruthenium layer on a substrate, the method comprising:
providing a substrate within a deposition system;
introducing a purge gas to said deposition system;
heating said substrate in said deposition system to a deposition temperature;
heating a ruthenium carbonyl precursor in a vaporization system to form a ruthenium carbonyl precursor vapor;
mixing said CO gas with said metal carbonyl precursor vapor to form a process gas;
establishing a flow of said process gas to an exhaust system without introducing said flow of process gas to said deposition system for a duration of time sufficient to create a stable flow rate of said process gas;
terminating said introducing of said purge gas to said deposition system;
after said duration of time, and after or concurrently with said terminating, introducing said flow of process gas at said stable flow rate to said deposition system; and
exposing said substrate at said deposition temperature to said process gas to deposit a ruthenium layer on said substrate by a vapor deposition process.

19. A computer readable medium containing program instructions for execution on a deposition system, which when executed by the deposition system, cause the deposition system to perform the steps of:
providing a substrate within said deposition system;
introducing a purge gas to said deposition system;
heating said substrate in said deposition system to a deposition temperature;
establishing a flow of process gas containing a metal carbonyl precursor vapor and a CO gas to an exhaust system without introducing said flow of process gas to said deposition system for a duration of time;
terminating said introducing of said purge gas to said deposition system;
after said duration of time, and after or concurrently with said terminating, introducing said flow of process gas to said deposition system; and
exposing said substrate to said process gas at said deposition temperature to deposit a metal layer on said substrate by a vapor deposition process.
